(19) United States
(12) Patent Application Publication
(10) Pub. No.: US 2025/0180621 A1
(43) Pub. Date: Jun. 5, 2025

(54) REAL-TIME FAULT MONITORING SYSTEM

(71) Applicant: DARRYL MENDIVIL, San Luis Obispo, CA (US)

(72) Inventor: DARRYL MENDIVIL, San Luis Obispo, CA (US)

(21) Appl. No.: 18/916,620

(22) Filed: Oct. 15, 2024

Related U.S. Application Data
(63) Continuation of application No. 18/365,747, filed on Aug. 4, 2023.
Application No. 18/365,747 is a continuation-in-part of application No. 17/173,144, filed on Feb. 10, 2021.
(60) Provisional application No. 62/972,640, filed on Feb. 10, 2020.
(60) Provisional application No. 63/590,322, filed on Oct. 13, 2023.
(60) Provisional application No. 63/549,368, filed on Feb. 2, 2024.

(51) Int. Cl. G01R 31/08; B60W 60/00

(52) U.S. Cl. CPC G01R 31/085; B60W 60/001; B60W 2300/14; B60W 2420/403

(57) ABSTRACT

A real-time fault monitoring system has a bi-spectrum infrared and visible-light camera and a wireless transmitter that transmits a video signal from the camera to a remote server. The camera is mounted in a location and position to monitor temperatures of components in susceptible to catastrophic failure, for example, in the nacelle of a wind turbine or the inverter housing of a solar power system. The server monitors the infrared video signal for temperature anomalies and causes an alert to be sent to an end-user if a heat signature measured using the infrared image exceeds a predetermined level or falls outside a predetermined range. The server also provides access to live video stream and recorded video of the infrared and visible-light imaging for real-time human observation and the ability to analyze where and when a fault initially occurred.

### RELATED APPLICATIONS

This application claims priority to U.S. Utility patent application Ser. No. 18/365,747 for a “Real-Time Fault Detection and Infrared Inspection System” currently pending, which claims priority to U.S. Utility patent application Ser. No. 17/173,144 for “Real-Time Fault Detection and Infrared Inspection System” currently pending, which claims priority to U.S. Provisional Patent Application Ser. No. 62/972,640 for “Real-Time Fault Detection and Infrared Inspection System”, and further claims priority to U.S. Provisional Patent Application Ser. No. 63/590,322 for a “Real-Time Wind Turbine Fault Monitoring System,” filed Oct. 13, 2023, and U.S. Provisional Patent Application Ser. No. 63/549,368 for a “Real-Time Fault Monitoring System,” filed Feb. 2, 2024. The above-mentioned applications are fully incorporated herein by reference as if set forth herein in their entirety.

### FIELD OF THE INVENTION

The present invention pertains generally to fault detection systems. The present invention is more particularly related to fault detection in wind generators, solar inverters, and other electrical generation and distribution systems. The present invention is well suited for the real-time monitoring of power systems to accurately and efficiently identify conditions that can lead to fire or other catastrophic system failure.

### BACKGROUND OF THE INVENTION

Wind turbines are a popular source of clean energy and generally operate by rotors that turn wind energy into rotational energy, which is in turn converted into electricity by a generator. Modern large wind turbines can produce more than a megawatt of power, with some modern wind turbines achieving outputs of tens of megawatts.

However, wind turbines are prone to catastrophic failure. One of the most common causes of wind turbine accidents is fire. Once a fire breaks out, there is often no real option other than to wait for the fire to burn out on its own; meanwhile, if the rotor blades are turning, the generator can continue operating, creating additional heat that further weakens the structure and exacerbates the fire situation. Although many turbines include brakes, it can be difficult or impossible to quickly bring large, fast-moving blades—which extend three hundred feet or more in some turbines—to a halt. Fires tend to cause severe structural damage, often resulting in a total loss of the wind turbine.

Apart from the dangers presented by structural damage, such as collapse or rotor blades flying off the tower, there is a potentially enormous economic cost to failure, since the cost of large wind turbines is in the millions of dollars, and even smaller turbines with output measured in mere kilowatts can cost fifty thousand dollars or more.

Likewise, equipment failure can present problems and fire risk in other installations related to the generation and distribution of electrical power. For example, inverters used with solar arrays, transformers, power lines, high voltage power panels, and switchgears are all potential points of failure. Battery energy storage facilities can catch fire, contaminating the air and posing other regional environmental risks in addition to the fire itself resulting in electrical grid impacts, and the cost of damage to the facilities themselves can be significant. Fires in facilities using lithium-ion batteries are particularly difficult to extinguish, due in part to thermal runaway.

In view of the above, it would be advantageous to provide a system that can report faults in a wind turbine that allows for the braking of the blades or other measures to be taken before catastrophic failure occurs. It would be further advantageous to provide a system that can detect and report faults in multiple types of power systems, that is, in electrical generation and distribution equipment.

### SUMMARY OF THE INVENTION

Disclosed is a real-time fault monitoring system that is particularly useful for monitoring potential faults in electrical generation and distribution equipment and predicting failures before they occur. A preferred embodiment includes a real-time wind turbine fault monitoring system. Preferred embodiments include an infrared camera mounted in the nacelle to monitor temperatures of the components inside and a wireless transmitter that transmits a video signal from the camera to a monitoring system such as an internet-connected server.

In other preferred embodiments, the cameras are mounted in inverter cabinets for solar arrays, battery storage facilities, utility vaults, utility and transmission lines, hydroelectric power stations, battery energy storage facilities, or manufacturing facilities. An exemplary embodiment is incorporated into a manufacturing facility to streamline component manufacturing processes with efficient inspection and condition monitoring, thus protecting critical connections in order to maximize manufacturing uptime. Cameras can be mounted in multiple sites to provide real-time monitoring, e.g., in multiple solar sites, or in both solar and wind generation facilities together with utility lines, or other combinations as needed for a particular purpose.

In preferred embodiments, the server receiving the signal from the camera monitors the signal for temperature anomalies and causes an alert to be sent to an end-user if a heat signature measured using the infrared image exceeds a predetermined level or falls outside a predetermined range. In some preferred embodiments, computer vision technology incorporating machine learning is also used to monitor infrared and visible-light video signals for potential hazards, including temperature anomalies, equipment breakage, and other hazardous conditions. The server also provides access to live video stream and recorded video for both real-time human observation and the ability to analyze where and when a fault initially occurred.

In preferred embodiments, the camera is a bi-spectrum camera that captures visible light images as well as infrared, thus enabling a user to monitor both an infrared video stream and a visible light video stream.

The system provides alarm alerts with reports predicting fire hazard, arc flashes, nacelle break areas, and failures in converter cabinets and transformers.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 illustrates the components of a typical wind turbine;

FIG. 2 illustrates a wind turbine with on-site components of a preferred embodiment of a real-time wind turbine fault monitoring system installed;

FIG. 3 is a high-level diagram of components of a preferred embodiment of a real-time wind turbine fault monitoring system;

FIG. 4 is a diagram of a solar array;

FIG. 5 is a front view of an inverter of a solar array with a bi-spectrum camera mounted on the inside of the housing door as part of a real-time fault monitoring system;

FIG. 6 illustrates a real-time fault monitoring system implemented at an electrical substation;

FIG. 7 illustrates a visible-color camera view from a real-time fault monitoring system observing a wildfire at a distance;

FIG. 8 illustrates an infrared camera view from a real-time fault monitoring system observing a wildfire at a distance;

FIG. 9 is a high-level diagram of components of a preferred embodiment of a real-time fault monitoring system;

FIG. 10 is a high-level diagram of components of a preferred embodiment of a real-time fault monitoring system in conjunction with wind turbines solar arrays and utility lines;

FIG. 11 is a front view of a bi-spectrum camera used in a preferred embodiment of a real-time wind turbine fault monitoring system;

FIG. 12 is a side view of the bi-spectrum camera of FIG. 11;

FIG. 13 is a rear view of the bi-spectrum camera of FIG. 11;

FIG. 14 illustrates a dashboard user interface for remote monitoring via a preferred embodiment of a real-time wind turbine fault monitoring system; and

FIG. 15 is a flow chart illustrating an exemplary monitoring and alert process performed by a preferred embodiment of a real-time fault monitoring system.

### DETAILED DESCRIPTION

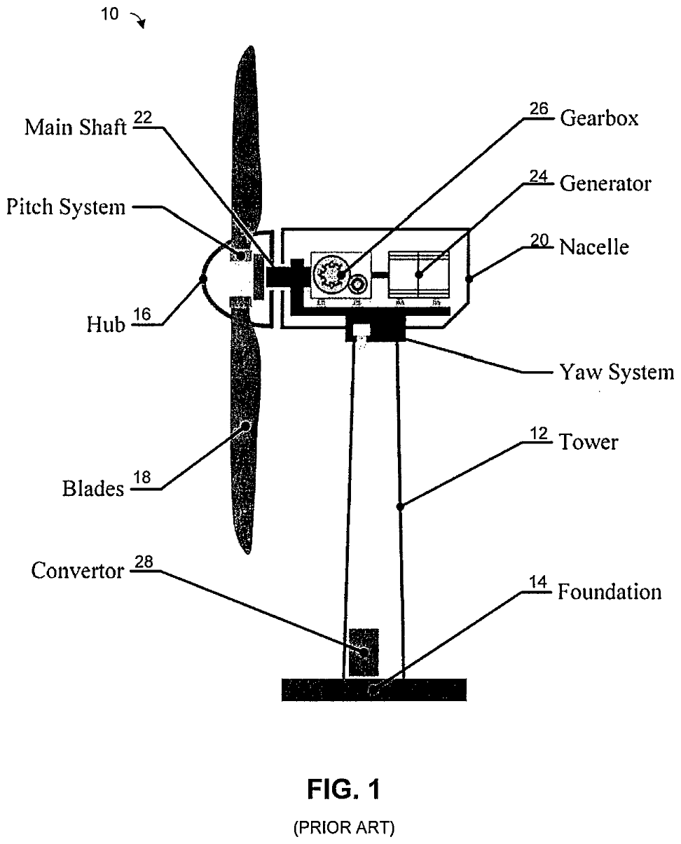

Referring initially to FIG. 1, a typical wind turbine for electricity generation is illustrated and generally labeled 10. Wind turbine 10 includes tower 12 installed on a foundation 14. At the top of tower 12 is hub 16 attaching blades 18 to nacelle 20 such that the blades 18, rotated by the wind, turn shaft 22 to provide mechanical power to generator 24. In some models, a gearbox 26 provides a transmission to provide a different rotational speed to the generator 24. At the base of tower 12 is a utility box 28 which has a converter or other hardware for adapting the generated electricity to a form desired for use, e.g., providing an appropriate frequency and phase for the electrical grid.

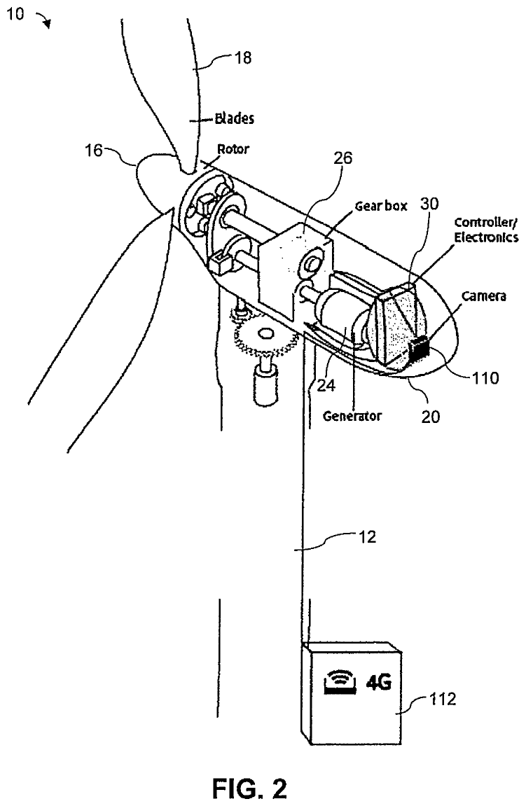

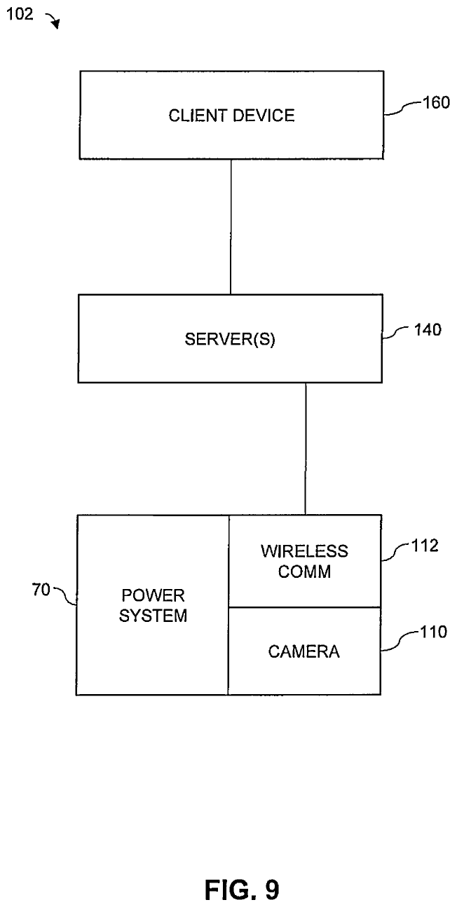

Referring now to FIG. 2, in a preferred embodiment of a real-time wind turbine fault monitoring system 100 (see FIG. 9), a camera 110 is installed in the nacelle 20 of a wind turbine 10 such that camera 110 captures images of its components, including generator 24 and associated electronics 30, as well as gearbox 26 and other contents of interest in nacelle 20.

In preferred embodiments, camera 110 has a thermal image sensor in order to capture infrared video. In this way, temperature measurements of generator 24, electronics 30, and other components inside nacelle 20 can be made. Some preferred embodiments of camera 110 also include a visible light sensor to capture black-and-white and color video from inside the nacelle 20.

Video imaging captured from camera 110 is provided to a wireless communication device 112, which sends the video signal to remote monitoring equipment, such as server 140 (as shown in FIG. 9). In a preferred embodiment, wireless communication device 112 includes a cellular modem and supporting electronics in order to send video using a network provided by a cellular carrier.

In some preferred embodiments, wireless communication device 112 is mounted at the base of tower 12, in or near utility box 28. Other embodiments in which wireless communication device 112 is located elsewhere, including near camera 110 in nacelle 20, are fully contemplated herein. Some preferred embodiments include additional cameras 110 located in areas of interest, such as in one or more of utility box 28, within tower 12, or elsewhere.

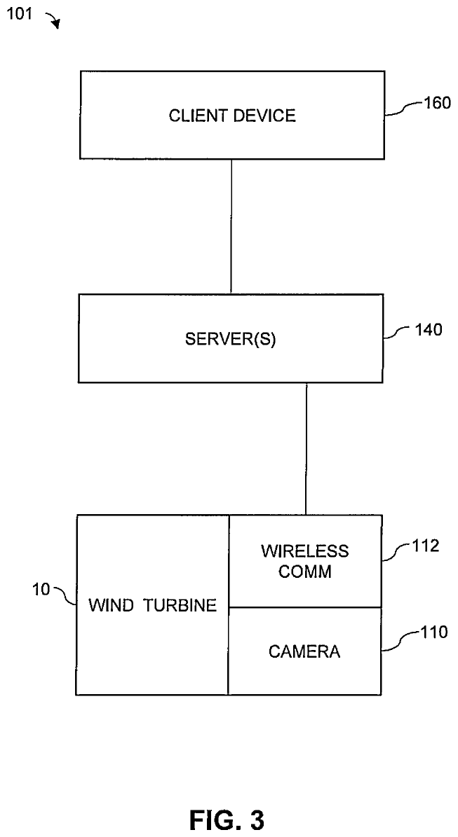

Referring now to FIG. 3, a diagram of a preferred embodiment of a real-time wind turbine fault monitoring system 101 is illustrated. Camera 110 is mounted on wind turbine 10; in preferred embodiments, camera 110 is located in the nacelle 20 (see FIG. 1), and in some preferred embodiments additional cameras 110 monitor other parts of wind turbine 10, as discussed above. Wireless communication device 112, also located on or next to wind turbine 10 in preferred embodiments, receives a video signal from camera 110 and provides it to one or more servers 140.

Although a single wind turbine 10 with an associated camera 110 and wireless communication device 112 is illustrated for clarity, preferred embodiments include systems 101 installed for use with multiple wind turbines 10, each with their own associated camera 110 or multiple cameras 110. In some embodiments, each wind turbine 10 has its own wireless communication device 112 to provide the feed from camera 110 to a server 140, while in other embodiments a wireless communication device 112 is shared between multiple wind turbines 10. For example, a wind farm may include anywhere from a few to several hundred wind turbines 10; system 101 is designed to operate with and monitor any number of desired wind turbines 10. Each wind turbine 10 is linked to server 140 or servers 140 through its own or a shared communication device 112.

In a preferred embodiment, servers 140 include a central management server, a database server, a media distribution server, and an intelligent analysis server. The intelligent analysis server provides image or pattern recognition capabilities for artificial intelligence supported monitoring, such as using deep learning algorithms to detect fire, smoke, and other potentially urgent issues. It will be apparent to one of ordinary skill in the art that these servers can share hardware, operating together on a single or a few computing devices, or each operate on their own hardware. Moreover, any of the servers can operate on multiple computing devices to provide additional computing resources as necessary for its task. They can also be implemented on cloud platforms, including “serverless” computing platforms.

In a preferred embodiment, servers 140 provide automated real-time monitoring, warning an end-user of temperature anomalies or other identified hazards, such as providing an alert when a temperature exceeds a predetermined threshold; providing an alert when smoke, fire or another anomalous situation is detected; or providing both types of alerts. In typical embodiments, these alerts are provided to a client device 160, such as a computer, tablet, mobile phone, or other computing device. Servers 140 also provides live access to infrared and visible light video feeds to an end user accessing servers 140 through a client device 160, and further provide the ability for a user using client device 160 to review recorded video from the infrared and visible light feeds. That is, video is provided both live and recorded at the same time so that a user can navigate to video captured at previous points in time, for example to research the origins of a fault.

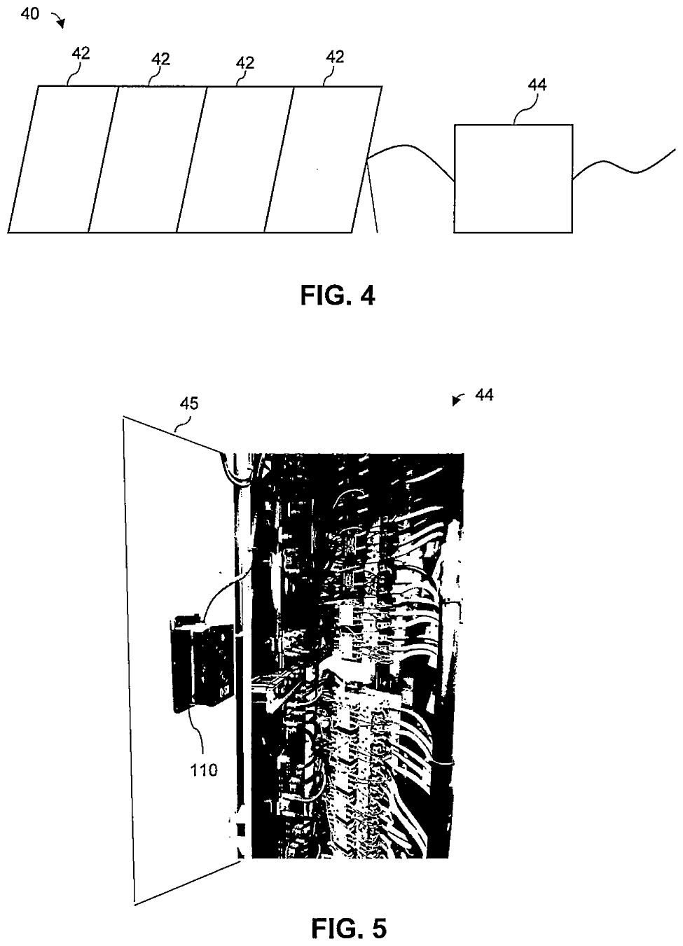

Referring now to FIG. 4, an exemplary solar array 40 is illustrated. Solar array 40 includes solar panels 42 and an inverter 44.

Referring now to FIG. 5, an inverter 44 is illustrated with its housing door 45 open to show camera 110 mounted on the inside of door 45. In this configuration, camera 110 is situated to monitor the inverter and warn a user of temperature anomalies or other hazards as described previously with respect to wind turbine 10 (see FIG. 2).

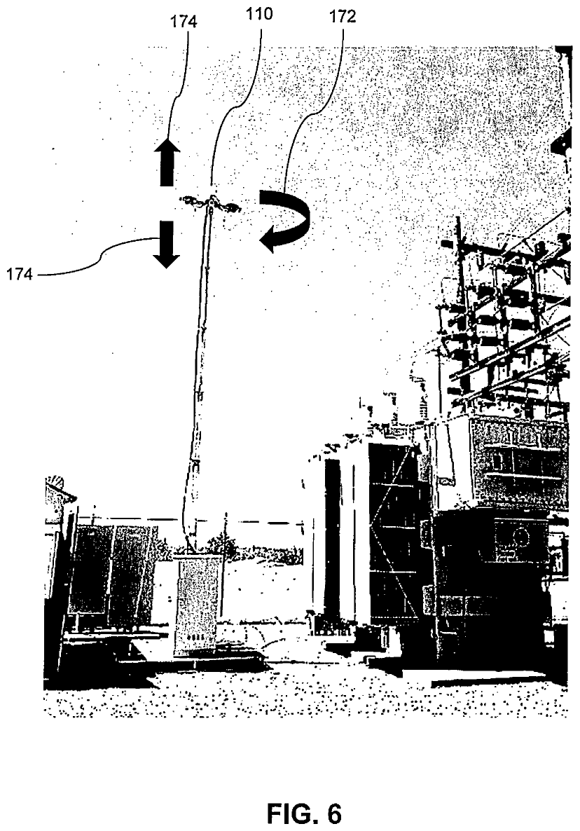

Referring now to FIG. 6, a preferred embodiment of a real-time fault monitoring system 100 is shown as implemented at a power substation. Camera 110 is mounted so that it can observe the switchgears and other components of the substation. FIG. 6 also illustrates the pan 172 and tilt 174 capabilities of camera 110, provided by the mounting equipment in preferred embodiments. Pan 172, tilt 174, and zoom capabilities allow for better observation of the power substation, or, in other embodiments, the power system being monitored, and in particular allow users to direct the camera and zoom in to better view a potential problem area. In some embodiments, the pan 172, tilt 174, and zoom capabilities further allow for external threats to be observed, e.g., by panning and zooming camera 110 to view areas outside the substation or other installation being monitored.

Although a power substation is shown, camera 110 can be mounted in a similar manner in other situations, including away from any power systems. For example, an alternative preferred embodiment of a real-time fault monitoring system includes cameras 110 mounted as illustrated in FIG. 6 on mountains or in other open areas to monitor wildfires and other hazards.

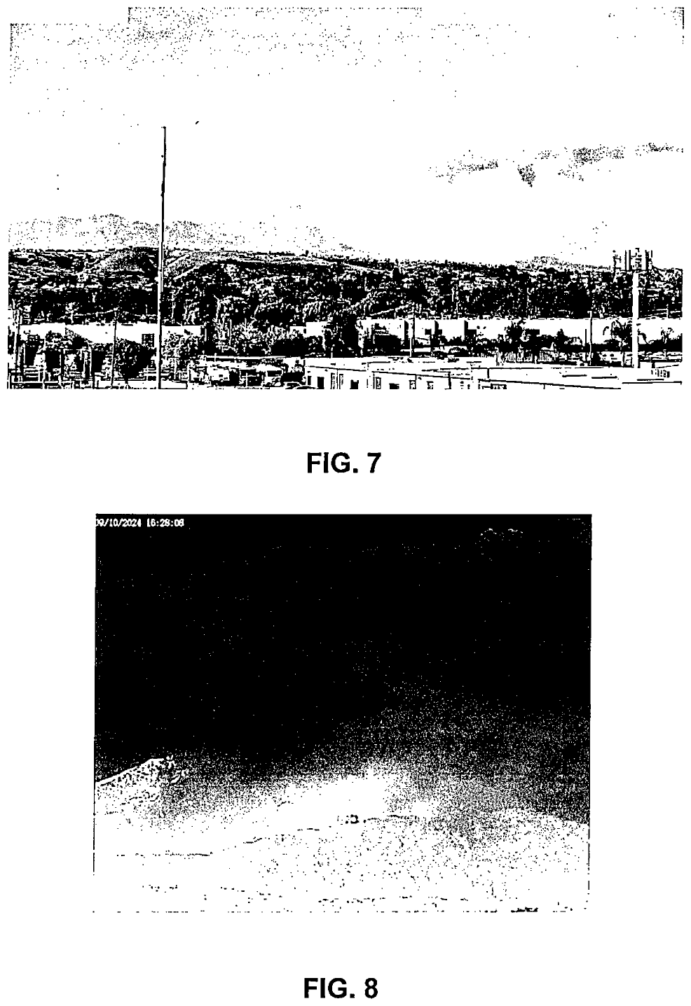

FIG. 7 illustrates a camera 110 view of a real-time fault monitoring system 100 viewing a wildfire. A camera 110 as part of a real-time fault monitoring system 100 mounted in an installation such as an electrical substation can provide a view of a wildfire in the region, as can a camera 110 installed on a mountaintop or other open area as part of a real-time fault monitoring system 100 used specifically for regional hazards such as wildfires.

A wildfire viewed from camera 110 may be obscured by smoke in the visible-light view, as seen in FIG. 7. However, the thermal or infrared view, as shown in FIG. 8, is able to observe the fire itself despite smoke obscuring the visible-light view.

Referring now to FIG. 9, a diagram of a preferred embodiment of a real-time fault monitoring system 102 is illustrated. Camera 110 is mounted on power system 70, or otherwise such that it is able to observe power system 70. Power system 70 is an apparatus related to electrical generation, storage, transmission, distribution, or use. Exemplary power systems 70 include wind turbines, solar inverters, transmission lines, transformers, switchgears, battery energy storage facilities, power panels (e.g. at manufacturing facilities), generators, and other devices for power generation, distribution, or storage. In some preferred embodiments additional cameras 110 monitor other parts of the installation in which power system 70 operates. For example, a large system generating grid power may have multiple inverters, transformers, and other equipment necessary to provide a large amount of power suitable for distribution to grid customers. Cameras 101 are used in some embodiments to monitor this equipment. Wireless communication device 112, also located on or next to power system 70 in preferred embodiments, receives a video signal from camera 110 and provides it to one or more servers 140.

Although a single power system 70 with an associated camera 110 and wireless communication device 112 is illustrated for clarity, preferred embodiments include systems 101 installed for use with multiple power systems 70 and other equipment, for example, as part of a single solar array 40 (see FIG. 4) or multiple solar arrays 40, each with their own associated camera 110 or multiple cameras 110. In some embodiments, each power system 70 or other piece of monitored equipment has its own wireless communication device 112 to provide the feed from camera 110 to a server 140, while in other embodiments a wireless communication device 112 is shared between multiple power systems 70.

In some embodiments, such as a mountaintop camera 110 for observing wildfires, power system 70 is not part of the setup. In these embodiments, wireless communication device 112 is simply attached to or otherwise located near camera 110 in order to provide communication capabilities.

In a preferred embodiment, servers 140 include a central management server, a database server, a media distribution server, and an intelligent analysis server. The intelligent analysis server provides image or pattern recognition capabilities for artificial intelligence supported monitoring, such as using deep learning algorithms to detect fire, smoke, and other potentially urgent issues. It will be apparent to one of ordinary skill in the art that these servers can share hardware, operating together on a single or a few computing devices, or each operate on their own hardware. Moreover, any of the servers can operate on multiple computing devices to provide additional computing resources as necessary for its task. They can also be implemented on cloud platforms, including “serverless” computing platforms.

In a preferred embodiment, servers 140 provide automated real-time monitoring, warning an end-user of temperature anomalies or other identified hazards, such as providing an alert when a temperature exceeds a predetermined threshold; providing an alert when smoke, fire or another anomalous situation is detected; or providing both types of alert. In typical embodiments, these alerts are provided to a client device 160, such as a computer, tablet, mobile phone, or other computing device. Servers 140 also provide live access to infrared and visible light video feeds to an end user accessing servers 140 through a client device 160, and further provide the ability for a user using client device 160 to review recorded video from the infrared and visible light feeds. That is, video is provided both live and recorded at the same time so that a user can navigate to video captured at previous points in time, for example to research the origins of a fault.

By monitoring power system 70, faults can be detected before an equipment failure or an associated hazard such as a fire breaks out. This allows for repairs to be made and saves the cost of damage associated with catastrophic failure. Moreover, environmental harm can be avoided in many cases. For example, fires at a lithium-ion battery energy storage facility can release toxic gases, including hydrogen fluoride, into the air, and the rate of release of hydrogen fluoride can increase with the application of water to suppress the fire. Thermal runaway makes lithium-ion battery fires difficult to suppress. As a result, identifying a fault before a fire breaks out has the potential to avoid significant potential harm to the environment and people near a lithium-ion battery energy storage facility.

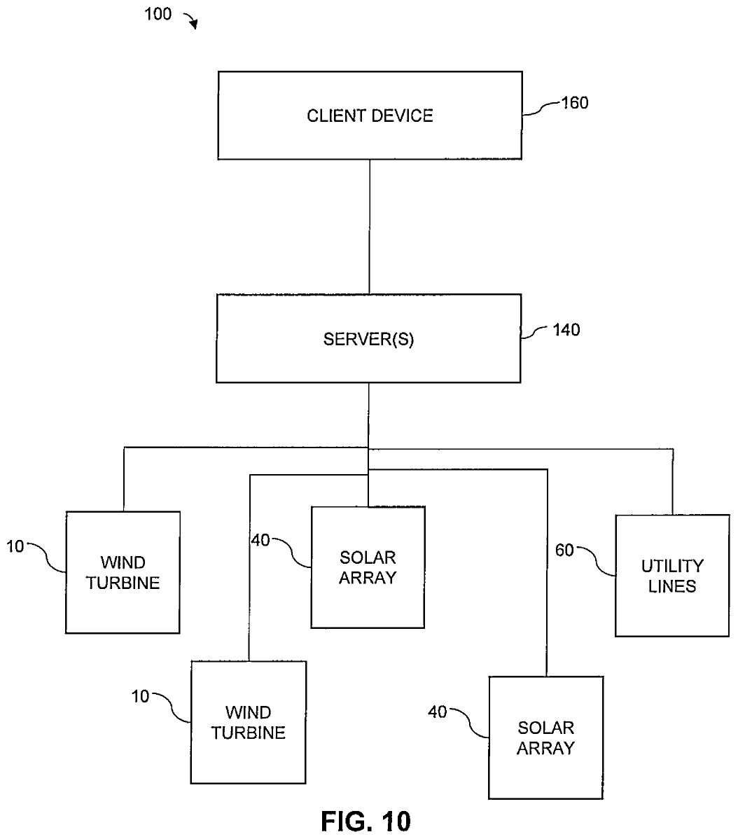

Referring now to FIG. 10, a conceptual diagram of a real-time fault monitoring system is illustrated and generally designated 100. Specific embodiments of system 100 were described in more particular detail as system 101 (see FIG. 3) and system 102 (see FIG. 9).

For illustrative purposes, system 100 is shown with a variety of monitored power systems, including wind turbines 10, solar arrays 40, and utility lines 60, each having its own camera 110 (not shown in FIG. 10) and wireless communication device 112 (not shown in FIG. 10) to connect to server 140 and ultimately provide data and alerts to client device 160 as described in detail above in connection with FIGS. 3 and 6. It will be apparent to one of ordinary skill in the art that system 100 is capable of working with additional types of power systems, such as transformers, switchgears, high voltage power panels, batteries, inverters, utility vaults, and other equipment in a variety of situations including power generation and distribution, manufacturing facilities, and other situations in which real-time fault monitoring may be useful. Since inclusion of each individual possible type of monitored power equipment in the diagram is not necessary for understanding the subject matter of the invention, they are not shown in FIG. 10; however, they would be connected to server 140 in the same manner as illustrated equipment, wind turbines 10, solar arrays 40, and utility lines 60 are connected, and more particularly in a configuration analogous to that shown in FIGS. 3 and 6.

The variety of monitored equipment is presented in FIG. 10 for illustrative purposes. A typical implementation may have a variety of equipment as illustrated, including types of monitored equipment not explicitly shown, or may have instances of only a single type of equipment. Each combination is fully contemplated herein.

For example, an electrical power distribution service may implement system 100 with cameras 110 (not shown in FIG. 10) to monitor utility lines 60, as well as to monitor switchgears and transformers (not shown) in substations. The service may purchase some of its power from a wind farm operating its own separate system 100 having multiple wind turbines 10 monitored. A manufacturing facility may implement system 100 with power panels as the monitored equipment, and, if partially solar powered, may also monitor solar inverters 44 (see FIG. 4) with system 100.

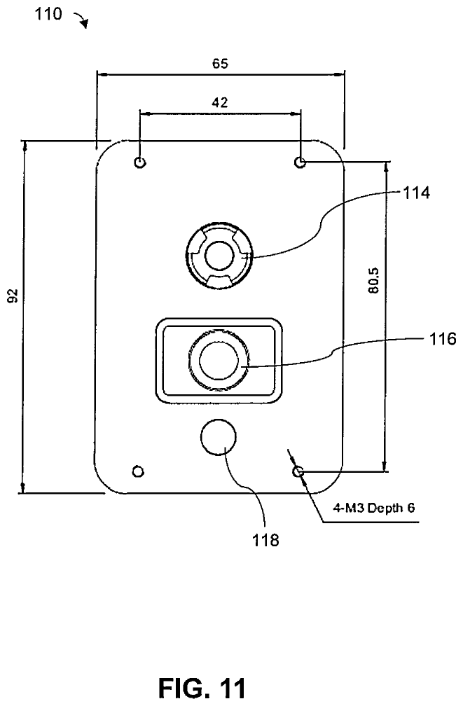

Referring now to FIG. 11, a preferred embodiment of camera 110 is a bi-spectrum camera with an infrared or thermal camera 114 and a visible light camera 116. An exemplary embodiment of thermal camera 114 is a bolometer that has a spectral range of approximately eight (8) to fourteen (14) micrometers and a resolution of at least two hundred fifty-six (256) pixels by one hundred ninety-two (192) pixels, scalable to at least seven hundred four (704) pixels by five hundred seventy-six (576) pixels, a thermal sensitivity of sixty-five (65) millikelvins or less at three hundred (300) kelvin, an aperture of F1.0, a horizontal viewing angle of ninety-five (95) degrees, and a vertical viewing angle of seventy-five (75) degrees.

An exemplary embodiment of visible light camera 116 uses a complementary metal-oxide semiconductor (CMOS) image sensor, such as those provided in conjunction with the mark SONY, and has an effective resolution of at least one thousand nine hundred twenty (1920) pixels by one thousand eighty (1080) pixels, a variable shutter speed, a variable aperture of up to F2.0, fixed focus, a horizontal viewing angle of one hundred thirty-six point two (136.2) degrees, and a vertical viewing angle of seventy-seven point three (77.3) degrees. It is functional at F1.2 aperture with at least 0.1 lux of illumination for color imaging, and at least 0.01 lux of illumination for black and white imaging.

Both thermal camera 114 and visible light camera 116 in the above-mentioned exemplary embodiments provide video of at least twenty-five (25) and thirty (30) frames per second.

Some preferred embodiments of camera 110 include an additional temperature detection sensor 118 capable of at least three temperature measurement rule types, including spot, line, and area temperature measurements at an operational range of negative forty (−40) degrees Fahrenheit to three hundred two (302) degrees Fahrenheit.

Preferred embodiments of camera 110 communicate with wireless communication device 112 (see FIG. 1) through an RJ-45 jack for an ethernet cable, a USB interface, or via video output through a BNC or RS485 interface. Over the ethernet interface Unicast streaming directly from camera 110 is supported. Embodiments with each possible combination of one or more of the above-mentioned interfaces are fully contemplated, as are the use of other interfaces known in the art.

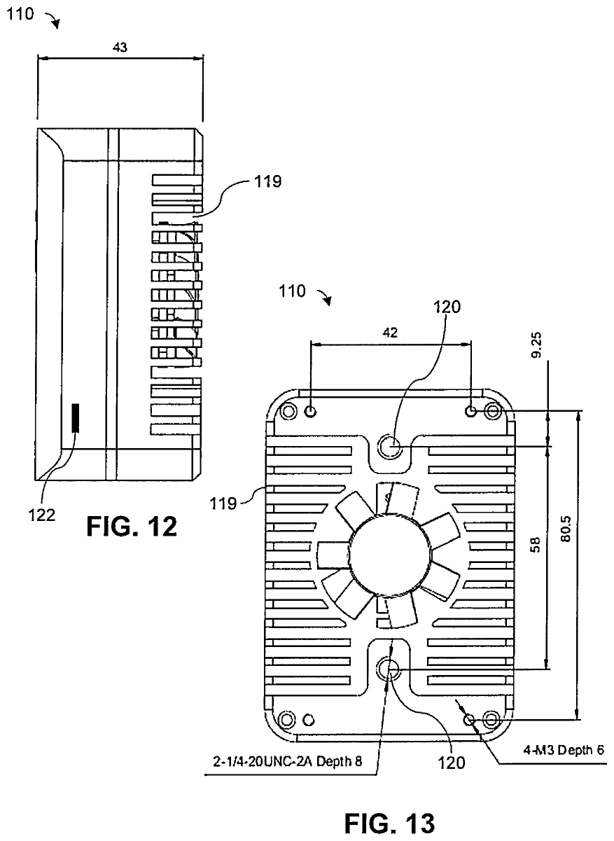

Referring now to FIG. 12, a side view of camera 110 is illustrated, showing ventilation slots 119 present to prevent overheating in some preferred embodiments. Preferred embodiments of camera 110 include a Secure Digital (SD) card port 122 or other port or connector for a removable mass storage device, allowing for data including video data from camera 110 to be stored and transferred without network access. This allows camera 110 to be operable during network outages or without a network (thus providing an “air gap” when security requirements necessitate one), and backup access to the data in case of loss from server 140 (shown in FIG. 10) or a network attack or other event that may raise questions to the reliability of video transferred to server 140 or client 160 (shown in FIG. 10).

Referring now to FIG. 13, mounting apertures 120 allow for camera 110 to be mounted directly to a wall or other existing structure, or to a separate mounting accessory. Some embodiments of such an accessory include an actuator, rail, or worm and gear system, a motorized panning and tilting bracket, a servo for tilting, or a combination thereof in order to allow remote-controlled movement and adjustment of the position and angle of camera 110.

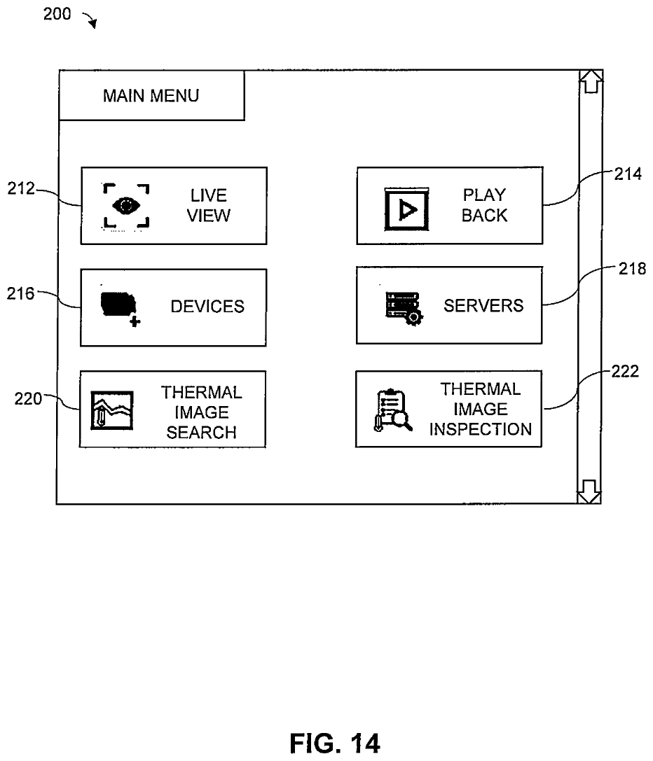

Referring now to FIG. 14, an exemplary user interface dashboard is illustrated and generally designated 200. Dashboard is displayed by client device 160 (shown in FIG. 9) as an application-such as a web application or mobile application-accessing services provided by servers 140 (shown in FIG. 9). Exemplary application elements include live view 212 through which a user views live video streams, play back 214 for viewing recorded video, such as to trace a fault back to its origin in time. Devices element 216 allows for configuration on monitoring of cameras 110 on separate wind turbines 10, for example, in preferred embodiments of system 100 (shown FIG. 9) in which multiple wind turbines 10 are present, each with its own camera 110 or cameras 110. Servers 218 element allows for configuration of the servers 140 (shown in FIG. 9). Thermal image search 220 element and thermal image inspection element 222 provide easier access for a user to find recorded images from a previous point in time.

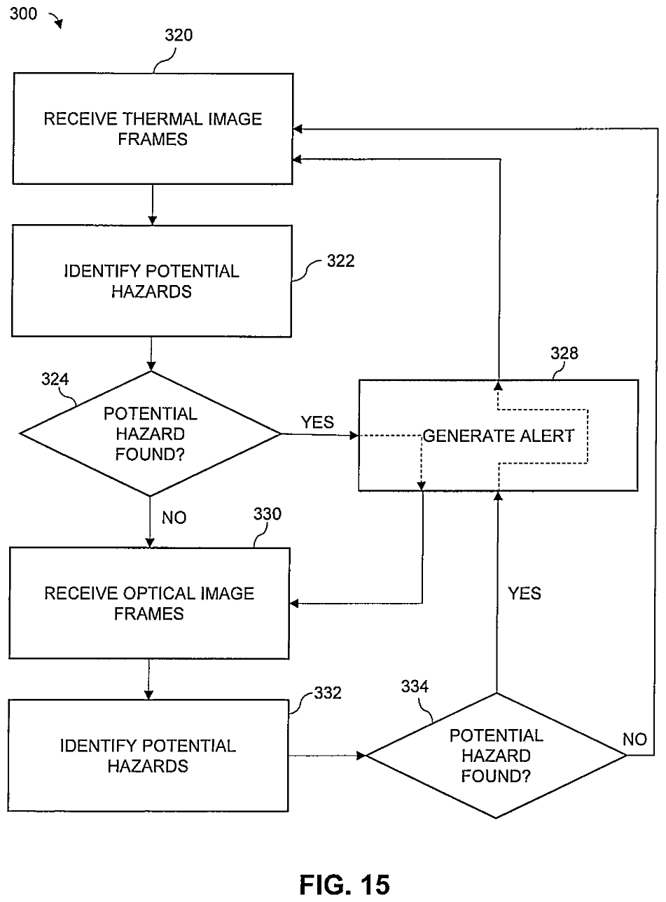

Referring now to FIG. 15, a simple diagram of a process 300 for identifying hazards is illustrated. Process 300 or a similar process is performed by server 140 (shown in FIG. 10) in preferred embodiments of real-time fault monitoring system 100 (shown in FIG. 10), including preferred embodiments of system 101 (shown in FIG. 3) and system 102 (shown in FIG. 9). Process 300 or a similar process is performed on client device 160 (shown in FIG. 10) in some alternate embodiments, and in some preferred embodiments in which camera 110 (shown in FIG. 11) provides imaging directly to a client device 160 (shown in FIG. 10) without intervening servers 140 (shown in FIG. 10).

As video from the thermal camera 114 (shown in FIG. 11) is received in step 320, potential hazards are identified in step 322. The various pattern recognition techniques known in the art can be used in this step, but a preferred embodiment uses statistical techniques associated with machine learning to identify hazards. Upon finding a potential hazard in step 324, an alert is generated in step 328 and, in preferred embodiments, sent to a client device 160 (shown in FIG. 10) as discussed previously. The monitoring process 300 continues.

Video from the visible light camera 116 (shown in FIG. 11) is received in step 330 and analyzed to identify potential hazards in step 332. Step 332 is performed in the same manner as step 322, using computer vision techniques such as machine learning to identify hazards. When a potential hazard is found in step 334, an alert is generated in step 328 and, in preferred embodiments, sent to a client device 160 (shown in FIG. 10). The process 300 continues in a loop for continuous monitoring.

The steps of process 300 have been illustrated and described sequentially in order to provide a clear explanation of the process. It will, however, be apparent to a person of ordinary skill in the art that various steps of the process can be performed simultaneously. For example, video frames can continue to be received in steps 320 and 330 while previously received frames are analyzed in steps 322 and 332. Likewise, monitoring thermal video as described in steps 320, 322, and 324 can be performed concurrently with monitoring visible-light video as described in steps 330, 332, and 334. Embodiments that implement concurrency in the monitoring process and other computer processes are fully contemplated herein.

While there have been shown what are presently considered to be preferred embodiments of the present invention, it will be apparent to those skilled in the art that various changes and modifications can be made herein without departing from the scope and spirit of the invention.

What is claimed is:

1. A real-time fault monitoring system, comprising:
one or more camera installations, each camera installation comprising:
a thermal camera positioned to monitor a power system, and
a wireless communication device in communication with the thermal camera and configured to receive a video signal from the thermal camera; and
a server configured to receive the video signals of the thermal cameras from the wireless communication devices, store the video from the video signals, and provide the video as an internet video feed.

2. The real-time fault monitoring system of claim 1, wherein the server monitors the video signals of the thermal cameras in real-time and sends an alert to a client device when a hazardous condition is detected.

3. The real-time fault monitoring system of claim 2, wherein hazardous conditions detected by the server include a temperature above a predetermined threshold.

4. The real-time fault monitoring system of claim 3, wherein the hazardous conditions detected by the server further include smoke and fire.

5. The real-time fault monitoring system of claim 4, wherein pattern recognition is employed by the server to detect smoke and to detect fire.

6. The real-time fault monitoring system of claim 5, wherein the pattern recognition is performed using a deep learning algorithm.

7. The real-time fault monitoring system of claim 1, wherein the thermal cameras are bi-spectrum cameras having a thermal imaging sensor and a visible light imaging sensor.

8. The real-time fault monitoring system of claim 1, wherein each camera installation further comprises a mounting accessory configured to allow remote-controlled movement and adjustment of the position and angle of the thermal camera.

9. A real-time fault monitoring system, comprising:
one or more client devices;
a server; and
a plurality of camera installations, each comprising:
a thermal camera, and
a wireless communication device in communication with the thermal camera and configured to receive a video signal from the thermal camera and provide it to the server,
wherein the server is configured to provide video from the video signals of the camera installations upon request to a client device of the one or more client devices, and
wherein the server is further configured to monitor the video signals for hazardous conditions and send an alert to at least one of the client devices when a hazardous condition is detected.

10. The real-time fault monitoring system of claim 9, wherein the thermal cameras are bi-spectrum cameras having a thermal imaging sensor and a visible light imaging sensor.

11. The real-time fault monitoring system of claim 9, wherein the hazardous conditions detected by the server include a temperature above a predetermined threshold.

12. The real-time fault monitoring system of claim 11, wherein the hazardous conditions detected by the server further include smoke and fire.

13. The real-time fault monitoring system of claim 12, wherein pattern recognition is employed by the server to detect smoke and to detect fire.

14. The real-time fault monitoring system of claim 13, wherein the pattern recognition is performed using a deep learning algorithm.

15. A real-time fault monitoring system, comprising:
a client device;
a server; and
a plurality of cameras, each camera positioned to obtain live video of a power system and communicate the live video to the server,
wherein the server is configured to monitor the live video for hazardous conditions with the aid of one or more artificial intelligence algorithms and send an alert to the client device when a hazardous condition is detected.

16. The real-time fault monitoring system of claim 15, wherein the server is further configured to provide the live video to the client device.

17. The real-time fault monitoring system of claim 15, wherein the thermal cameras are bi-spectrum cameras having a thermal imaging sensor and a visible light imaging sensor.

18. The real-time fault monitoring system of claim 15, wherein hazardous conditions detected by the server include a temperature above a predetermined threshold.

19. The real-time fault monitoring system of claim 15, wherein hazardous conditions detected by the server further include smoke and fire.

20. The real-time fault monitoring system of claim 15, further comprising a mounting accessory attached to a camera of the plurality of cameras, the mounting accessory configured to allow remote-controlled movement and adjustment of the position and angle of the camera.
